(19) United States
(12) Patent Application Publication
(10) Pub. No.: US 2026/0090032 A1
(43) Pub. Date: Mar. 26, 2026

(54) SEMICONDUCTOR DEVICE AND METHOD FOR FORMING THE SAME

(71) Applicant: TAIWAN SEMICONDUCTOR MANUFACTURING COMPANY LTD., HSINCHU (TW)

(72) Inventors: CHENG-WEI WU, TAICHUNG CITY (TW); LI-HSIN CHU, NEW TAIPEI CITY (TW); WEN-CHIH CHIANG, HSINCHU CITY (TW); YUNG-LUNG HSU, TAINAN (TW); BO-CHANG LAI, NEW TAIPEI CITY (TW)

(21) Appl. No.: 18/895,433

(22) Filed: Sep. 25, 2024

(51) Int. Cl. H01L 29/06; H01L 21/768; H01L 23/48; H01L 29/08

(52) U.S. Cl. CPC H10D 62/10; H10D 62/151; H10W 20/023; H10W 20/20

(57) ABSTRACT

A semiconductor device and a method for manufacturing the semiconductor device are provided. The semiconductor device includes a conductive structure, a gate structure, a first biasing structure and a second biasing structure. The conductive structure is formed on a substrate and extends along a first axis. The gate structure is formed above a central area of the conductive structure along a second axis vertical to the first axis. The gate structure extends beyond the central area along the first axis. The first biasing structure is spaced apart from the gate structure and at least partially embedded within a first recessed isolation of the conductive structure. The second biasing structure is spaced apart from the gate structure and at least partially embedded within a second recessed isolation of the conductive structure. The central area is between the first recess area and the second area along the first axis.

### BACKGROUND

The present disclosure relates, in general, to semiconductor devices and methods for manufacturing the same. Specifically, the present disclosure relates to semiconductor devices and methods for manufacturing semiconductor devices with additional biasing structures.

During the manufacturing process of the semiconductor device, forming the conductive or metal structure is a key step. However, the conductive or metal structure may not be flat and smooth, and may include at least one protruding structure in certain areas. As a result, the semiconductor device may be turned on early due to the undesired protruding structure. Therefore, modulating and controlling the early turned-on voltages becomes an issue.

### BRIEF DESCRIPTION OF THE DRAWINGS

Aspects of the embodiments of the present disclosure are best understood from the following detailed description when read with the accompanying figures. It should be noted that, in accordance with standard practice in the industry, various structures are not drawn to scale. In fact, the dimensions of the various structures can be arbitrarily increased or reduced for clarity of discussion.

FIG. 1A illustrates a cross-section view of a semiconductor device with biasing structures, in accordance with some embodiments of the present disclosure.

FIG. 1B illustrates an enlarged view of a protruding structure of a semiconductor device with biasing structures, in accordance with some embodiments of the present disclosure.

FIG. 1C illustrates a top view of a semiconductor device with biasing structures, in accordance with some embodiments of the present disclosure.

FIG. 2 illustrates a schematic of current and voltage curves of a semiconductor device with different biasing conditions, in accordance with some embodiments of the present disclosure.

FIG. 3 illustrates a cross-section view of a semiconductor device with biasing structures, in accordance with some embodiments of the present disclosure.

FIG. 4 illustrates a schematic of current and voltage curves of a semiconductor device with different biasing conditions, in accordance with some embodiments of the present disclosure.

FIG. 5 illustrates a cross-section view of a semiconductor device with multi-layer structures, in accordance with some embodiments of the present disclosure.

FIG. 6A to FIG. 6E are cross-section views illustrating the manufacturing of a semiconductor device with multi-layer structures, in accordance with some embodiments of the present disclosure.

FIG. 7 illustrates a cross-section view of a semiconductor device with multi-layer structures, in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

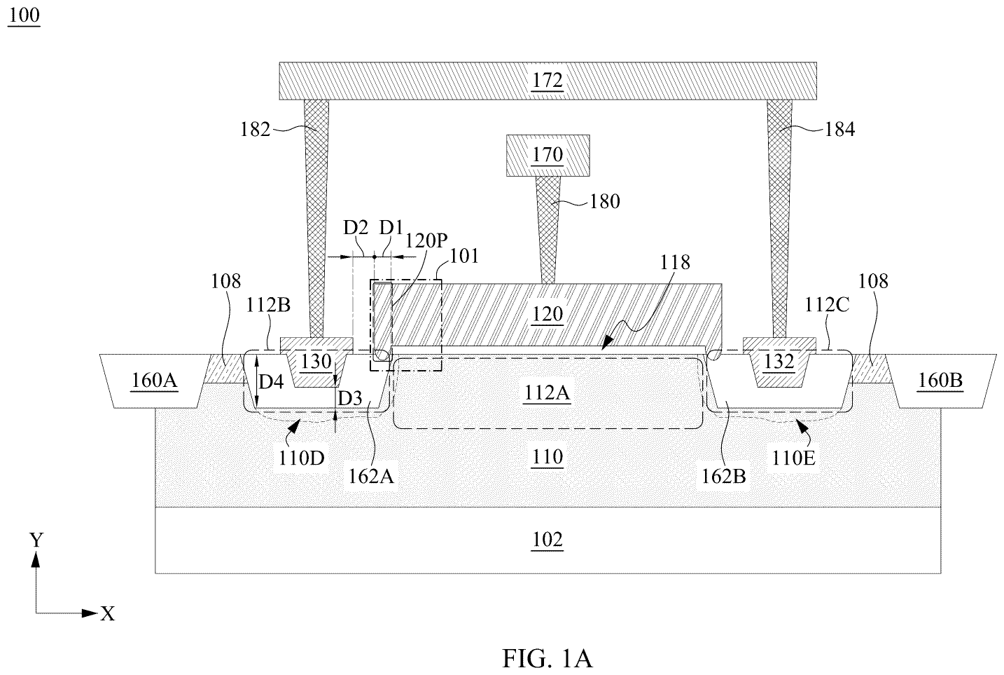

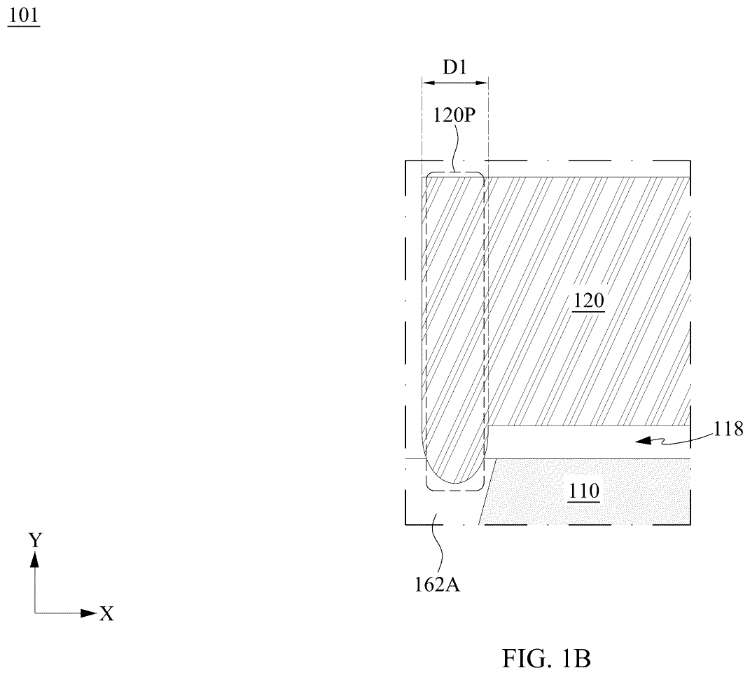

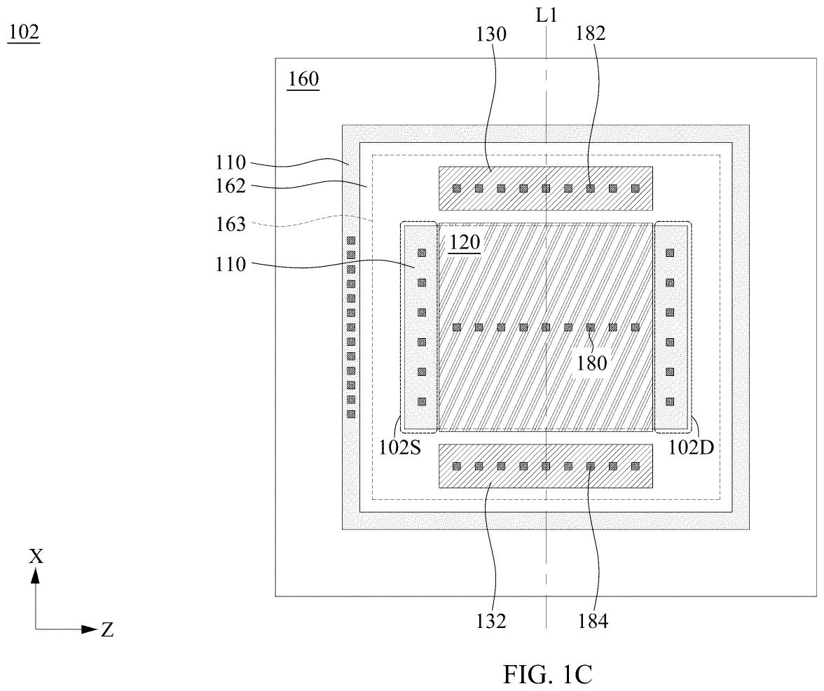

FIG. 1A illustrates a cross-section view of a semiconductor device 100 with biasing structures 130 and 132, in accordance with some embodiments of the present disclosure. The semiconductor device 100 can include a substrate 102, a conductive structure 110, a gate structure 120, two biasing structures 130 and 132, several insulating structures 160A, 160B, 162A, and 162B, and two contacts 170 and 172.

The semiconductor device 100 includes the substrate 102. In some embodiments, the substrate 102 may be a silicon substrate, a silicon germanium substrate, or a substrate formed of other semiconductor materials. In some embodiments, the substrate 102 may be doped with p-type dopants (such as boron or BF2), n-type dopants (such as phosphorus or arsenic), or a combination thereof. Alternatively, the substrate 102 may be an intrinsic semiconductor substrate. In alternative embodiments, the substrate 102 is a dielectric substrate formed of, for example, silicon oxide.

The conductive structure 110 can be disposed or formed on the substrate 102 along the Y axis. In some embodiments, a material of the conductive structure 110 may be the same or different from that of the substrate 102. For example, the conductive structure 110 may be made of a suitable elemental semiconductor, such as crystalline silicon, diamond, or germanium, a suitable compound semiconductor, such as gallium arsenide, silicon carbide, indium arsenide, or indium phosphide, or a suitable alloy semiconductor, such as silicon germanium carbide, gallium arsenic phosphide, or gallium indium phosphide.

The conductive structure 110 can be doped with dopants of the first conductivity type. The conductive structure 110 can be doped with dopants of the second conductivity type. In some embodiments, the first conductivity type is opposite to the second conductivity type. For example, the dopants of the first conductivity type may be p-type dopants and the dopants of the second conductivity type may be n-type dopants. In some embodiments, the p-type dopants include, for example, boron, BF2, or the like. On the other hand, the n-type dopants include, for example, phosphorus, arsenic, or the like.

As shown in FIG. 1A, the conductive structure 110 extends along the X axis vertical to Y axis. The conductive structure 110 can include a central area 112A and two recessed regions 112B and 112C along the X axis. The central area 112A is provided between the recessed regions 112B and 112C. The central area 112A and two recessed regions 112B and 112C are formed on an upper portion of the conductive structure 110, which is far away from the substrate 102 and close to the gate structure 120.

Each or some of the insulating structures 160A, 160B, 162A, and 162B may include a shallow trench isolation (STI). The insulating structures 160A, 160B, 162A, and 162B may be used for electrically isolating the semiconductor device 100 from another semiconductor device. The insulating structures 160A, 160B, 162A, and 162B may be used for physically isolating the semiconductor device 100 from another semiconductor device.

In some embodiments, the recessed region 112B is filled with the insulating structure 162A, and thus can also be referred to as recessed isolation 112B. The insulating structure 162A can be formed or embedded within the recessed region 112B. In some embodiments, the recessed region 112C is filled with the insulating structure 162B, and thus can also be referred to as recessed isolation 112C. The insulating structure 162B can be formed or embedded within the recessed region 112C. In addition, as shown in FIG. 1A, a bulk 108 can be formed between the insulating structures 160A and 160B. Another bulk 108 can be formed between the insulating structures 162A and 162B.

A material of the insulating structures 160A, 160B, 162A, and 162B can include silicon oxide, silicon nitride, titanium oxide, or the like. In some embodiments, the insulating structures 160A, 160B, 162A, and 162B can constitute multiple dielectric layers. The insulating structures 160A, 160B, 162A, and 162B may include, but are not limited to, molding compounds or pre-impregnated composite fibers (e.g., pre-preg). Examples of molding compounds may include, but are not limited to, an epoxy resin having fillers dispersed therein. Examples of a pre-preg may include, but are not limited to, a multi-layer structure formed by stacking or laminating a number of pre-impregnated materials/sheets.

In some embodiments, the gate structure 120 can be formed above the central area 112A of the conductive structure 110. The gate structure 120 can be of a rectangular-like shape and extend along the X axis. The gate structure 120 can have one or more protruding structures with a width D1 at the lateral sides. In some embodiments, a dielectric structure 118 can be formed between the gate structure 120 and the central area 112A. The dielectric structure 118 can be surrounded by the gate structure 120 and the conductive structure 110. The dielectric structure 118 can include silicon oxide, silicon nitride, titanium oxide, or the like. The dielectric structure 118 can constitute multiple dielectric layers. The dielectric structure 118 may include, but is not limited to, molding compounds or pre-impregnated composite fibers. Examples of molding compounds may include, but are not limited to, an epoxy resin having fillers dispersed therein.

The gate structure 120 can be electrically connected to the contact 170 for receiving a gate voltage to control or operate the semiconductor device 100. The gate voltage can be provided from an external power supply source. The gate structure 120 can be electrically connected to the contact 170 through the via 180. The via 180 may include or become a through silicon via (TSV). The gate structure 120, the contact 170 and the via 180 can be, or include, a conductive material such as a metal or metal alloy. Examples include aluminum, copper, chromium, tin, gold, silver, nickel or stainless steel, or a mixture, an alloy, or other combination thereof.

In some embodiments, the biasing structure 130 can be electrically connected to the contact 172 for receiving a biasing voltage to control or operate the semiconductor device 100. The biasing voltage can be provided from an external power supply source. The biasing voltage can be different from the gate voltage. The biasing structure 130 can be electrically connected to the contact 172 through the via 182. The via 182 may include or become a TSV. The biasing structure 130, the contact 172 and the via 182 can be, or include, a conductive material such as a metal or metal alloy. Examples include aluminum, copper, chromium, tin, gold, silver, nickel or stainless steel, or a mixture, an alloy, or other combination thereof.

The biasing structure 130 can be spaced apart from the gate structure 120. The biasing structure 130 can be substantially formed within the recessed isolation 112B. The biasing structure 130 is at least partially embedded within the recessed isolation 112B of the conductive structure 110. The biasing structure 130 can be partially surrounded or in direct contact with the insulating structure 162A. The biasing structure 130 can be completely surrounded or in direct contact with the insulating structure 162A.

As shown in FIG. 1A, the distance D2 is provided between the biasing structure 130 and the protruding structure 120P of the gate structure 120 along the X axis. The distance D3 is provided between the biasing structure 130 and a bottom of the recessed isolation 112B along the Y axis. The recessed isolation 112B can have a depth D4 along the Y axis. In some embodiments, the distance D2 is greater than the width D1 of the protruding structure 120P of the gate structure 120. In some embodiments, the distance D3 is greater than the width D1 of the protruding structure of the gate structure 120. In some embodiments, the distance D3 is greater than or substantially identical to the distance D2. In some embodiments, the depth D4 is greater than the distance D3 and the distance D2. In some embodiments, the width D1 can be greater than 50 nm. In some embodiments, the depth D4 can be in a range of 40 nm to 500 nm. In some embodiments, the distance D2 can be greater than 0.1 μm. In some embodiments, the distance D3 can be 50% to 70% of the depth D4. In some embodiments, the depth of the biasing structure 130 within the recessed isolation 112B can be 30% to 50% of the depth D4.

In some embodiments, the biasing structure 132 can be electrically connected to the contact 172 for receiving a biasing voltage to control or operate the semiconductor device 100. The biasing voltage can be provided from an external power supply source. The biasing voltage can be different from the gate voltage. The biasing structure 132 can be electrically connected to the contact 172 through the via 184. The via 184 may include or become a TSV. The biasing structure 132, the contact 172 and the via 184 can be, or include, a conductive material such as a metal or metal alloy. Examples include aluminum, copper, chromium, tin, gold, silver, nickel or stainless steel, or a mixture, an alloy, or other combination thereof.

The biasing structure 132 can be spaced apart from the gate structure 120. The biasing structure 132 can be substantially formed within the recessed isolation 112C. The biasing structure 132 is at least partially embedded within the recessed isolation 112C of the conductive structure 110. The biasing structure 132 can be partially surrounded or in direct contact with the insulating structure 162B. The biasing structure 132 can be completely surrounded or in direct contact with the insulating structure 162B.

In some embodiments, the biasing structures 130 and 132 can be in the same escalation level. In some embodiments, the biasing structures 130 and 132 can be in different escalation levels. In some embodiments, the gate structure 120 and the biasing structures 130 and 132 can be in the same escalation level. In some embodiments, the gate structure 120 and the biasing structures 130 and 132 can be in different escalation levels. The gate structure 120 can be in a higher escalation level than the biasing structures 130 and 132 along the Y axis.

When the bias voltage applied to the contact 172 is negative, two depletion regions 110D and 110E can be created or developed as shown in FIG. 1A. The area of the depletion regions 110D and 110E can be adjustable in response to the bias voltage and/or the gate voltage. The area of the depletion regions 110D and 110E can be increased as the amplitude of the bias voltage increases.

FIG. 1B illustrates an enlarged portion 101 of a protruding structure 120P of the semiconductor device 100 with biasing structures 130 and 132, in accordance with some embodiments of the present disclosure. Note that some elements may be omitted from the enlarged portion 101 of FIG. 1B for simplicity and clarity.

The protruding structure 120P can be generated or formed on the lateral side of the gate structure 120 during the manufacturing process of the semiconductor device 100. The protruding structure 120P can extend along the Y axis and toward the insulating structure 162A and the conductive structure 110. The protruding structure 120P can partially be in contact with the insulating structure 162A. The protruding structure 120P can be separated from or spaced apart from the insulating structure 162A. The dielectric structure 118 can be encircled or surrounded by the protruding structure 120P, the gate structure 120 and the conductive structure 110. The protruding structure 120P is close to but not electrically connected to the conductive structure 110. However, the semiconductor device 100 may be turned on early due to the protruding structure 120P.

FIG. 1C illustrates a top view 102 of a semiconductor device 100 with biasing structures 130 and 132, in accordance with some embodiments of the present disclosure. Note that some elements may be omitted from the top view 102 of FIG. 1C for simplicity and clarity. The semiconductor device 100 of FIG. 1A can correspond to the cross-sectional view along the line L1 of the top view 102 of FIG. 1C.

The insulating structure 160 of FIG. 1C can include the insulating structures 160A and 160B of FIG. 1A. The insulating structure 162 of FIG. 1C can include the insulating structures 162A and 162B of FIG. 1A. As shown in the top view 102, the insulating structure 162 can be formed within the conductive structure 110. The conductive structure 110 can be formed within the insulating structure 160. Furthermore, a doped region 163 with n-type dopants is provided within the insulating structure 162. The biasing structures 130 and 132 can extend along the Z axis, which is vertical to the X axis and the Y axis.

In some embodiments, the source region 102S can be formed in the right portion of the conductive structure 110. The source region 102S can be adjacent to and separated from the gate structure 120. In some embodiments, the drain region 102D can be formed in the left portion of the conductive structure 110. The drain region 102D can be adjacent to and separated from the gate structure 120. Source/drain region(s) may refer to a source or a drain, individually or collectively dependent upon the context.

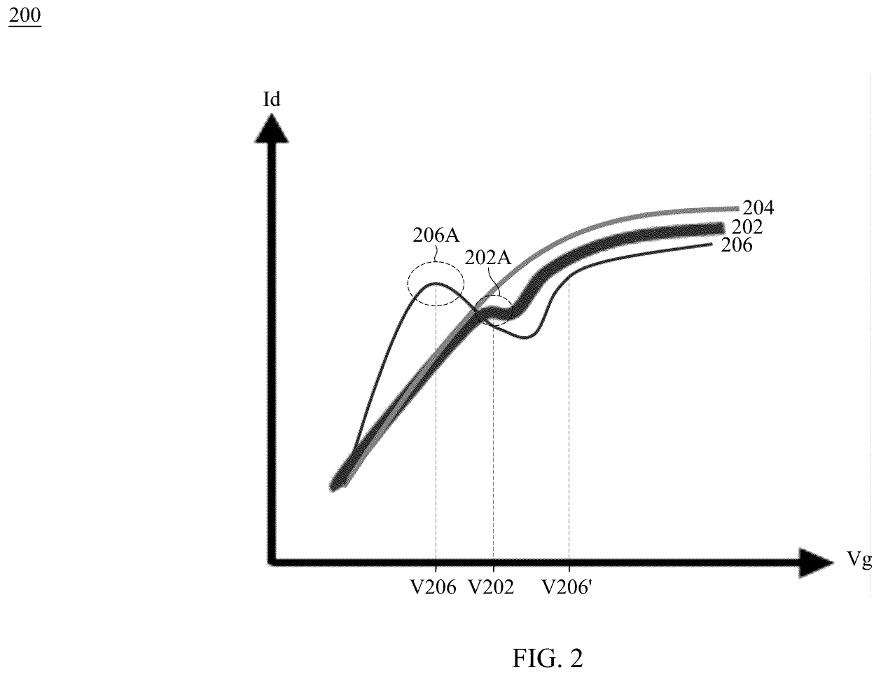

FIG. 2 illustrates a schematic 200 of current and voltage curves of the semiconductor device 100 with different biasing conditions, in accordance with some embodiments of the present disclosure. The current Id can correspond to the current passing from the drain region to the source region of the semiconductor device 100. The voltage Vg can correspond to the gate voltage applied to the contact 170 of the semiconductor device 100.

In some embodiments, the curve 202 can be generated when the biasing structures 130 and 132 are not provided for the semiconductor device 100. As shown in FIG. 2, the early turned-on phenomenon/characteristic (indicated by the early turned-on voltage V202) of the semiconductor device 100 exists or occurs in the area 202A of the curve 202, possibly due to the protruding structure 120P of the gate structure 120. The early turned-on voltage V202 can be reduced or controlled by providing the biasing structures 130 and 132 in association with corresponding biasing voltages.

In some embodiments, the curve 204 can be generated when the biasing structures 130 and 132 are provided for the semiconductor device 100. When the gate voltage and the biasing voltage have different polarities, the early turned-on phenomenon/characteristic (indicated by the early turned-on voltage V202) of the semiconductor device 100 can be avoided or eliminated. In some embodiments, the semiconductor device 100 can include an NMOS semiconductor device. The turned-on voltage to be applied to the gate structure 120 can be positive and can range from 2V to 3V. In addition, the biasing voltage is negative and can range from −2V to −10V. The variation of the biasing voltage can be greater than the variation of the gate voltage for creating the depletion area. Upon applying the gate voltage to the gate structure 120 and the biasing voltage to the biasing structures 130 and 132 with opposite polarities, the curve 204 can be created accordingly. As shown in FIG. 2, the curve 204 is smooth and lacks an early turned-on voltage.

In some embodiments, the curve 206 can be generated when the biasing structures 130 and 132 are provided for the semiconductor device 100. When the gate voltage and the biasing voltage have the same polarity, the early turned-on phenomenon/characteristic of the semiconductor device 100 can be enhanced or move forward to the turned-on voltage V206. The turned-on voltage V206 of the curve 206 is less than the turned-on voltage V202 of the curve 202, and thus the semiconductor device 100 can have an additional low threshold voltage, the turned-on voltage V206, for being operated in a switch mode. As a result, the resistance of the semiconductor device 100 in the switch mode can be reduced.

In some embodiments of the curve 206 with two turned-on voltages (threshold voltages) V206 and V206′, the semiconductor device 100 can include an NMOS semiconductor device. The gate voltage can be positive and can increase from 2V to 3V. In addition, the biasing voltage is positive and can increase from 2V to 10V. The variation of the biasing voltage can be greater than the variation of the gate voltage for creating the depletion area. Upon applying the gate voltage to the gate structure 120 and the biasing voltage to the biasing structures 130 and 132 with the same polarity, the curve 206 can be created accordingly. As shown in FIG. 2, the curve 206 has two turned-on voltages V206 and V206′, in which the turned-on voltage V206 is less than the turned-on voltage V202 of the curve 202.

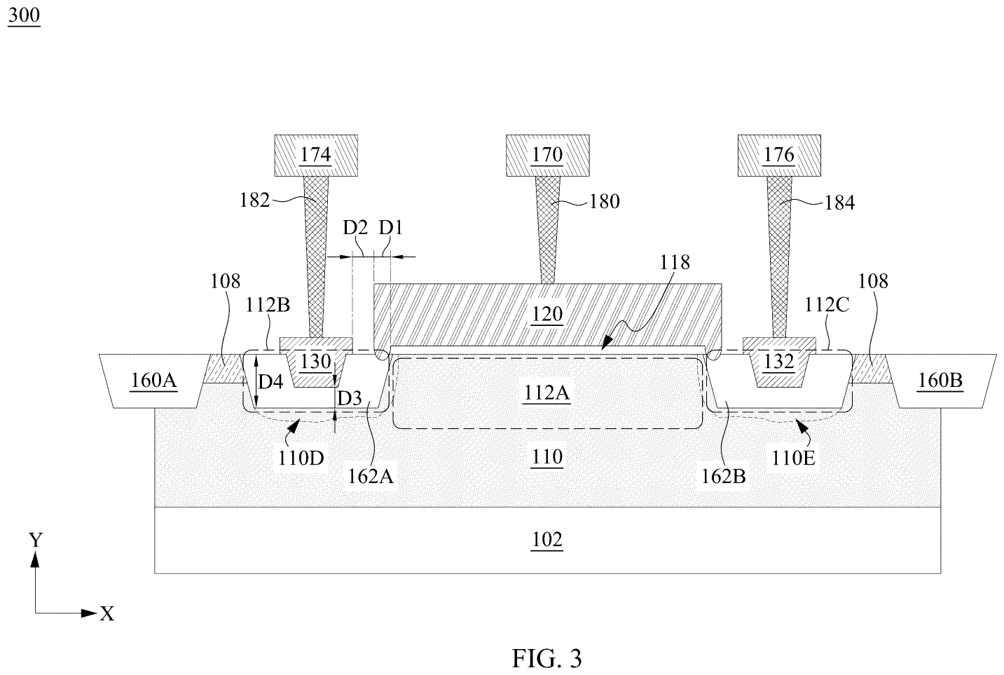

FIG. 3 illustrates a cross-section view of a semiconductor device 300 with biasing structures 130 and 132, in accordance with some embodiments of the present disclosure. The semiconductor device 300 of FIG. 3 can be similar to the semiconductor device 100 of FIG. 1A, except for the differences described as follows.

In some embodiments, the biasing structure 130 can be electrically connected to the contact 174 for receiving a first biasing voltage to control or operate the semiconductor device 300. The first biasing voltage can be provided from an external power supply source. The first biasing voltage can be different from the gate voltage. The biasing structure 130 can be electrically connected to the contact 174 through the via 182. The via 182 may include or become a TSV. The biasing structure 130, the contact 174 and the via 182 can be, or include, a conductive material such as a metal or metal alloy. Examples include aluminum, copper, chromium, tin, gold, silver, nickel or stainless steel, or a mixture, an alloy, or other combination thereof.

In some embodiments, the biasing structure 132 can be electrically connected to the contact 176 for receiving a second biasing voltage to control or operate the semiconductor device 300. The second biasing voltage can be provided from an external power supply source. The second biasing voltage can be different from the first biasing voltage and the gate voltage. The second biasing voltage can be identical to the first biasing voltage but different from the gate voltage. The biasing structure 132 can be electrically connected to the contact 176 through the via 184. The via 184 may include or become a TSV. The biasing structure 132, the contact 176 and the via 184 can be, or include, a conductive material such as a metal or metal alloy. Examples include aluminum, copper, chromium, tin, gold, silver, nickel or stainless steel, or a mixture, an alloy, or other combination thereof. In some embodiments, the biasing structures 130 and 132 can be electrically connected to different biasing voltages, and the turned-on voltages of the semiconductor device 300 can be modulated efficiently and effectively.

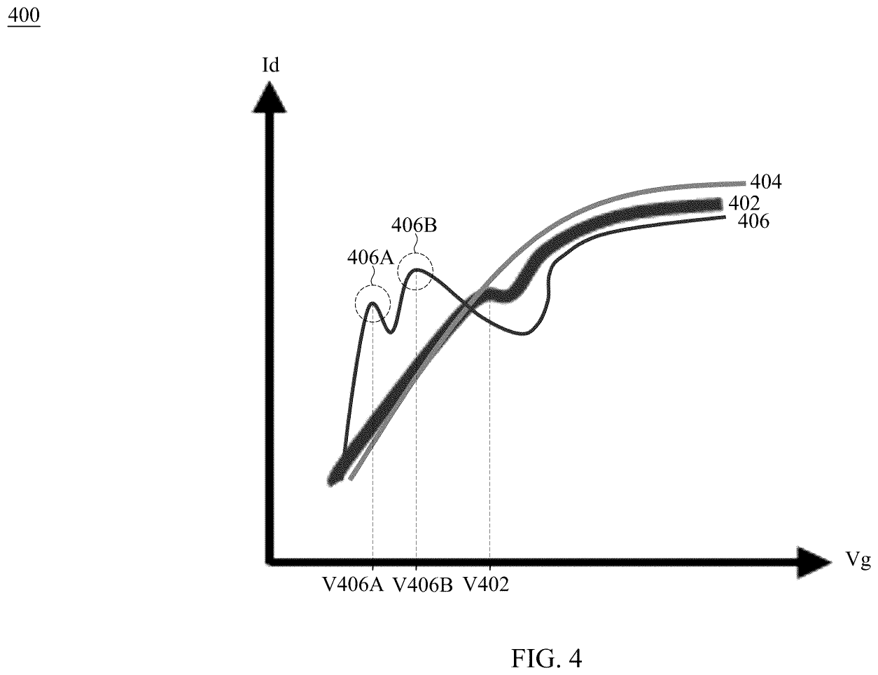

FIG. 4 illustrates a schematic 400 of current and voltage curves of a semiconductor device 300 with different biasing conditions, in accordance with some embodiments of the present disclosure. The current Id can correspond to the current passing from the drain region to the source region of the semiconductor device 300. The voltage Vg can correspond to the gate voltage applied to the contact 170 of the semiconductor device 300.

In some embodiments, the curve 402 can be generated when the biasing structures 130 and 132 are not provided for the semiconductor device 100. As shown in FIG. 4, the early turned-on voltage V402 exists or occurs on the curve 402, possibly due to the protruding structure 120P of the gate structure 120. The early turned-on voltage V402 can be reduced or controlled by providing the biasing structures 130 and 132 in association with different biasing voltages.

In some embodiments, the curve 404 can be generated when the biasing structures 130 and 132 are provided for the semiconductor device 300. When the gate voltage, the first biasing voltage and the second biasing voltage have different polarities (specifically, the gate voltage has a polarity different than that of the first biasing voltage and the second biasing voltage), the early turned-on voltage V402 of the semiconductor device 300 can be avoided or eliminated. In some embodiments, the semiconductor device 300 can include an NMOS semiconductor device. The gate voltage can be positive and can increase from 2V to 3V. In addition, the first biasing voltage and the second biasing voltage are negative and can decrease from −2V to −10V. The variation of the first and second biasing voltages can be greater than the variation of the gate voltage for creating the depletion area. Upon applying the gate voltage to the gate structure 120 and the first and second biasing voltages to the biasing structures 130 and 132 with opposite polarities, the curve 204 can be created accordingly. As shown in FIG. 4, the curve 404 is smooth, which means an early turned-on will not be seen on the semiconductor device 300.

In some embodiments, the curve 406 can be generated when the biasing structures 130 and 132 are provided for the semiconductor device 300. When the gate voltage and the first and second biasing voltages have the same polarity, the early turned-on voltage V402 of the semiconductor device 300 can be enhanced or move forward to the turned-on voltages V406A and V406B. The turned-on voltages V406A and V406B of the curve 406 are less than the turned-on voltage V402 of the curve 402, and thus the semiconductor device 300 can have two additional low threshold voltages, the turned-on voltages V406A and V406B, for being operated in a switch mode. As a result, the resistance of the semiconductor device 300 in the switch mode can be reduced.

In the embodiment of the curve 406 with two additional turned-on voltages V406A and V406B, the semiconductor device 300 can include an NMOS semiconductor device. The gate voltage can be positive and can range from 2V to 3V. In addition, the first biasing voltage is positive and can range from 2V to 10V. The second biasing voltage is positive and can range from 2V to 12V. The variation of the first and second biasing voltages can be greater than the variation of the gate voltage for creating the depletion area. The variation of the second biasing voltage can be greater than the variation of the first biasing voltage to generate two different early turned-on voltages. The second biasing voltage can be greater than the first biasing voltage, and thus the early turned-on voltage V406A can be less than the early turned-on voltage V406B.

Upon applying the gate voltage on the gate structure 120 and the first and second biasing voltages on the biasing structures 130 and 132 with the same polarity, the curve 406 can be created accordingly. As shown in FIG. 4, the curve 406 has two early turned-on voltages V406A and V406B which are less than the turned-on voltage V402 of the curve 402.

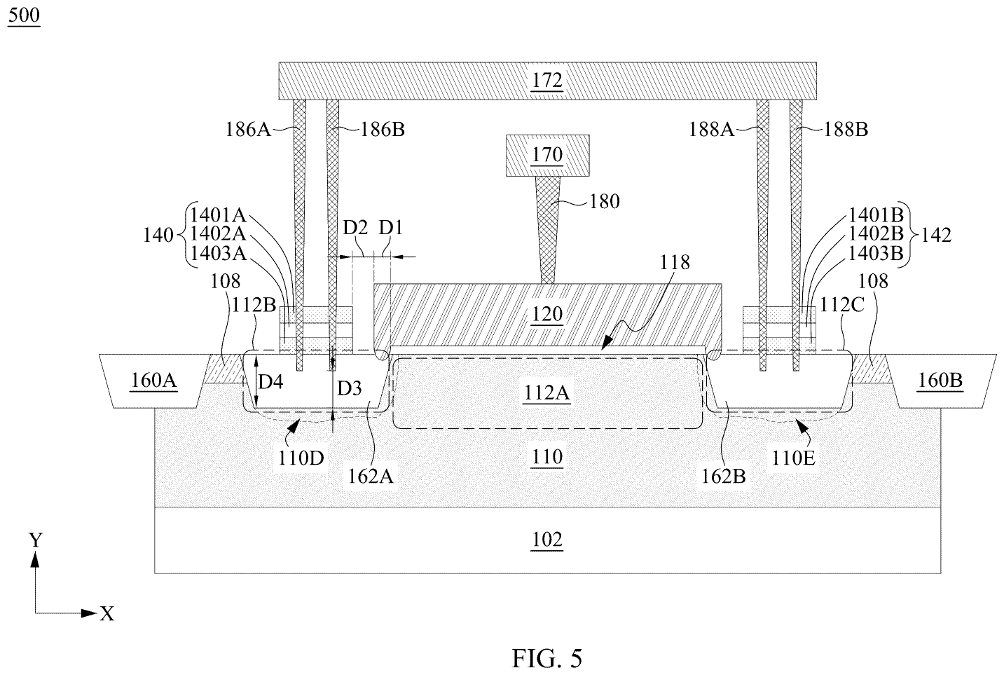

FIG. 5 illustrates a cross-section view of a semiconductor device 500 with multi-layer structures 140 and 142, in accordance with some embodiments of the present disclosure. The semiconductor device 500 of FIG. 5 can be similar to the semiconductor device 100 of FIG. 1A, except for the differences described as follows.

The semiconductor device 500 can include two multi-layer structures 140 and 142. The multi-layer structure 140 can be spaced apart from the gate structure 120. The multi-layer structure 140 can be formed on the recessed isolation 112B. The multi-layer structure 140 can be in direct contact with the recessed isolation 112B. The multi-layer structure 140 can be electrically connected to the contact 172 through a pair of vias 186A and 186B for receiving the biasing voltage. The vias 186A and 186B can penetrate the multi-layer structure 140. The vias 186A and 186B can extend into the insulating structure 162A.

The multi-layer structure 142 can be spaced apart from the gate structure 120. The multi-layer structure 142 can be formed on the recessed isolation 112C. The multi-layer structure 142 can be in direct contact with the recessed isolation 112C. The multi-layer structure 142 can be electrically connected to the contact 172 through a pair of vias 188A and 188B for receiving the biasing voltage. The vias 188A and 188B can penetrate the multi-layer structure 142. The vias 188A and 188B can extend into the insulating structure 162B.

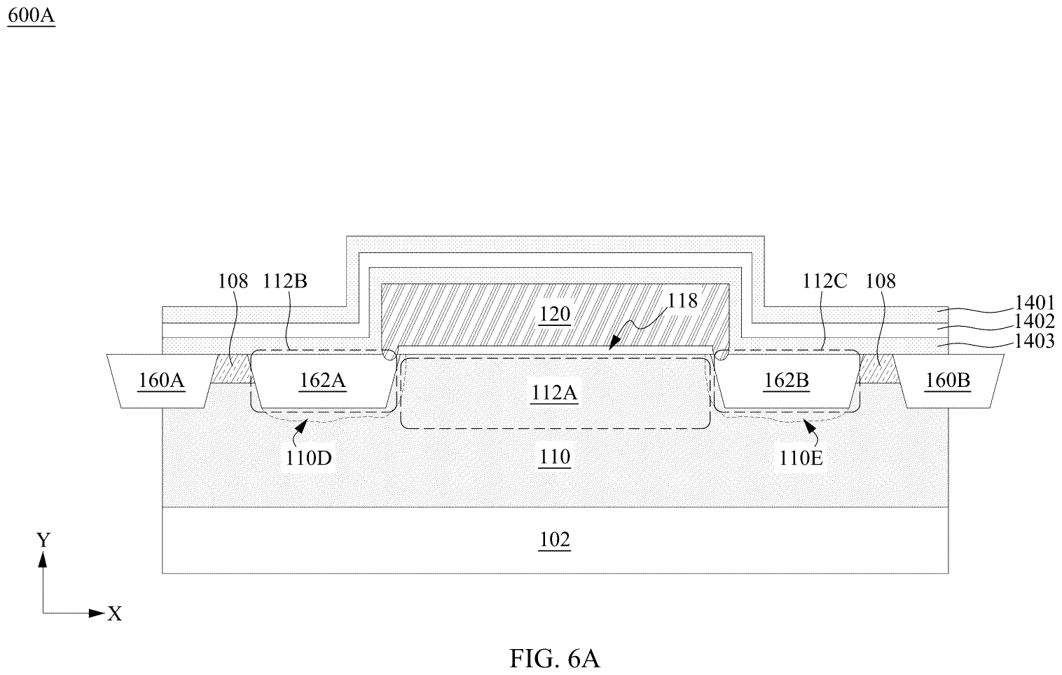

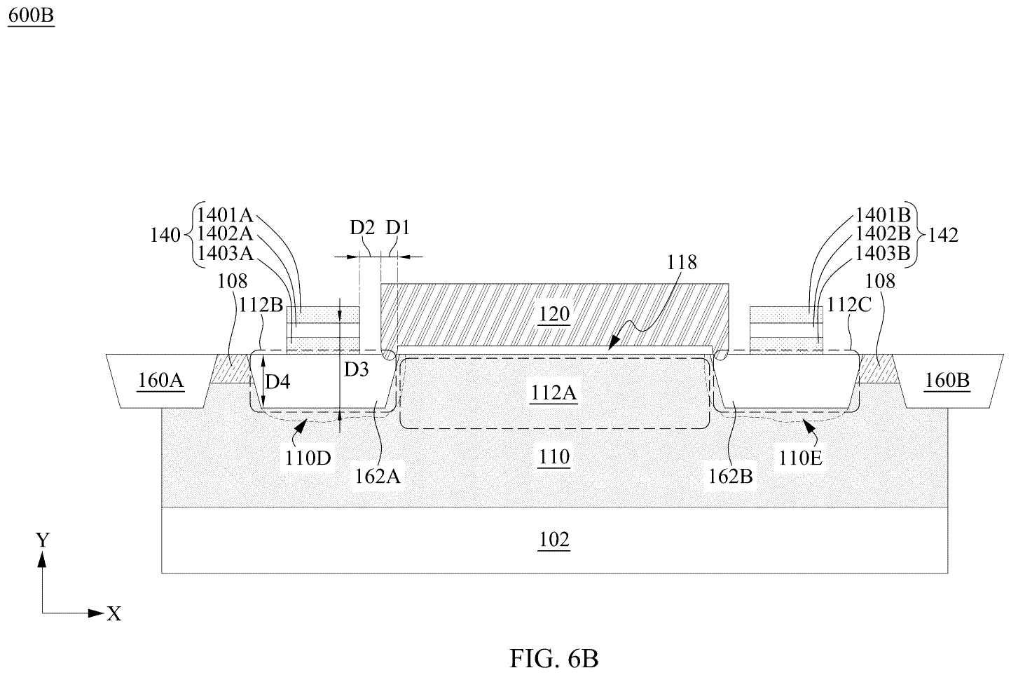

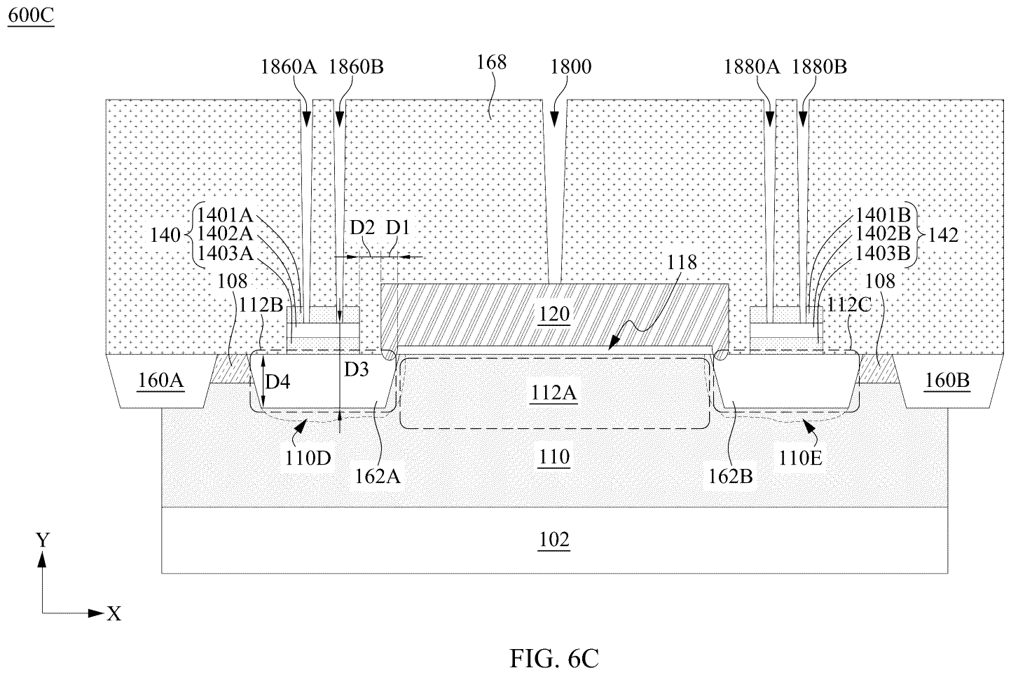

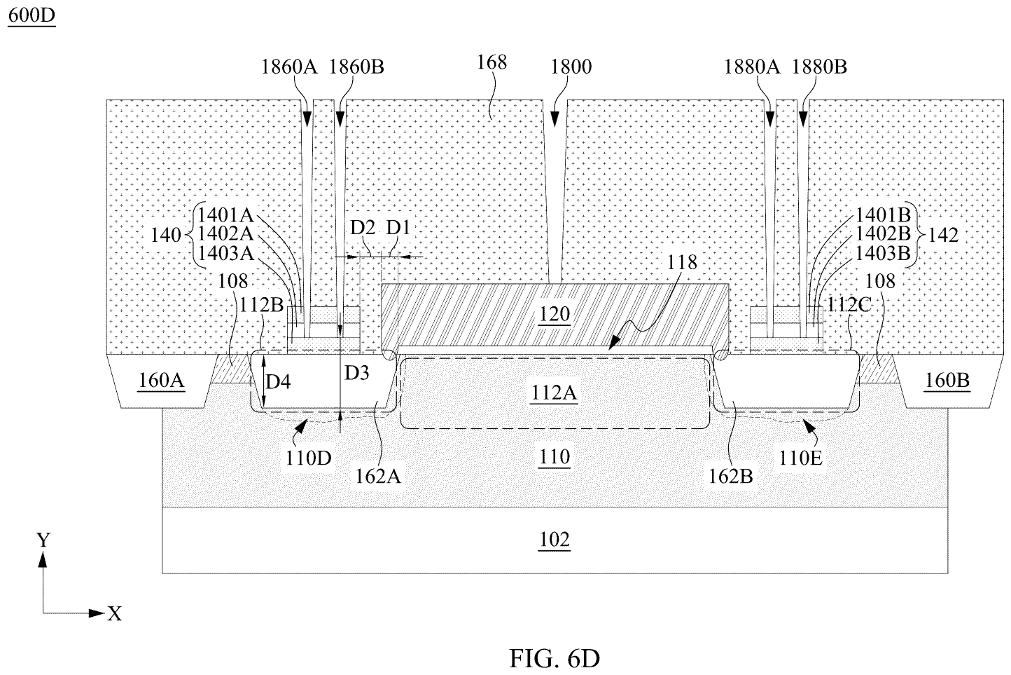

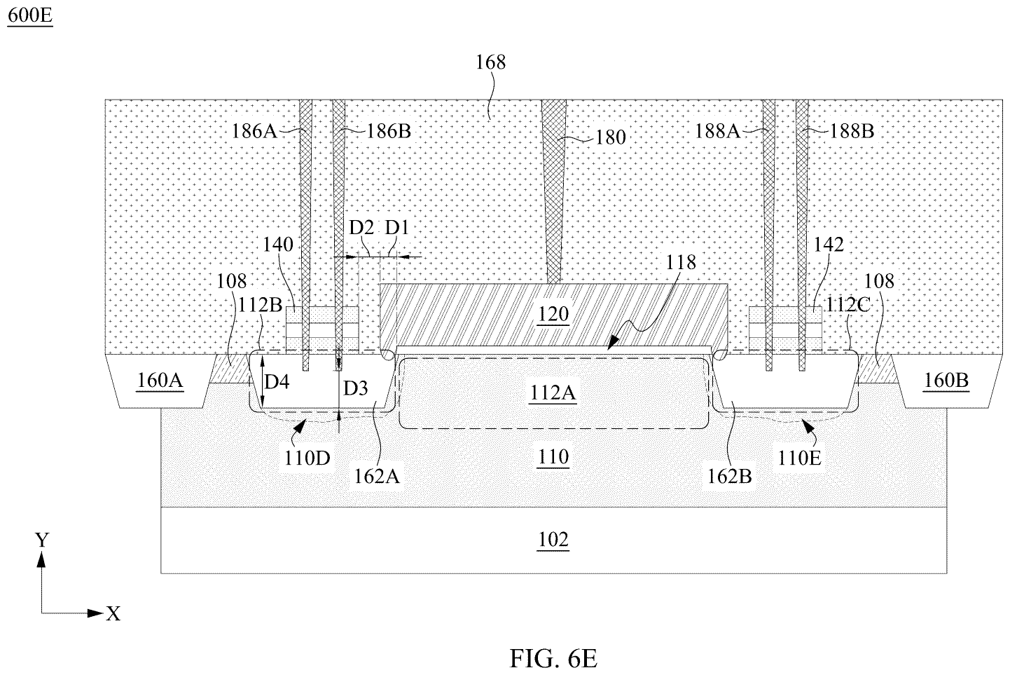

FIG. 6A to FIG. 6E are cross-section views illustrating the manufacturing of a semiconductor device 600 with multi-layer structures 140 and 142, in accordance with some embodiments of the present disclosure. As shown in the semiconductor device 600A of FIG. 6A, three dielectric layers are formed above the gate structure 120 and the insulating structures 160A, 160B, 162A and 162B. In some embodiments, the oxide layer 1403 can be deposited on the gate structure 120 and the insulating structures 160A, 160B, 162A and 162B. The nitride layer 1402 can be deposited on the oxide layer 1403. The oxide layer 1401 can be deposited on the nitride layer 1402. The nitride layer 1402 can include, for example, silicon nitride. Each of the oxide layers 1401 and 1403 can include, for example, silicon oxide.

In the embodiment of the semiconductor device 600B of FIG. 6B, etching can be executed on the oxide layer 1401, the nitride layer 1402 and the oxide layer 1403 to form the multi-layer structures 140 and 142. The multi-layer structure 140 includes a nitride layer 1402A sandwiched by two oxide layers 1401A and 1403A. The multi-layer structure 142 includes a nitride layer 1402B sandwiched by two oxide layers 1401B and 1403B. In some embodiments, each of the multi-layer structures 140 and 142 is made of an insulating material, and thus the distance D2 between the multi-layer structure 140 and the gate structure 120 can be reduced. In some embodiments, the distance D2 can be substantially zero. In some embodiments, each of the multi-layer structures 140 and 142 can include at least one resist protective oxide (RPO) film.

In the embodiment of the semiconductor device 600C of FIG. 6C, an oxide layer 168 can be deposited on the gate structure 120 and multi-layer structures 140 and 142. The oxide layer 168 can include a low-k interlayer dielectrics (ILD) oxide layer. Afterwards, the etching process can be performed on the oxide layer 168 to form the holes 1800, 1860A, 1860B, 1880A and 1880B, extending along the Y axis. The holes 1860A, 1860B, 1880A and 1880B can extend along the Y axis toward the conductive structure 110. The holes 1860A and 1860B can penetrate the oxide layer 1401A and contact the nitride layer 1402A. The holes 1880A and 1880B can penetrate the oxide layer 1401B and contact the nitride layer 1402B.

In the embodiment of the semiconductor device 600D of FIG. 6D, the holes 1860A and 1860B can penetrate the nitride layer 1402A. The holes 1880A and 1880B can penetrate the nitride layer 1402B. In the embodiment of the semiconductor device 600E of FIG. 6E, the holes 1800, 1860A, 1860B, 1880A and 1880B can be filled with a conductive material to form the vias 180, 186A, 186B, 188A and 188B. Furthermore, the vias 186A and 186B can penetrate the oxide layer 1403A as well as the whole multi-layer structure 140. The vias 188A and 188B can penetrate the oxide layer 1403B as well as the whole multi-layer structure 142.

In the embodiments of the semiconductor device 100 of FIG. 1 with the insulating structures 130 and 132, the RPO films are needed for manufacturing the semiconductor device 100. An additional mask will be required to form the insulating structures 130 and 132. However, in the embodiment of the semiconductor device 600 of FIG. 6, the multi-layer structures 140 and 142 can be manufactured in the same process for the RPO films. Therefore, compared to the semiconductor device 100 of FIG. 1, at least one mask can be saved or reduced for the semiconductor device 600 of FIG. 6.

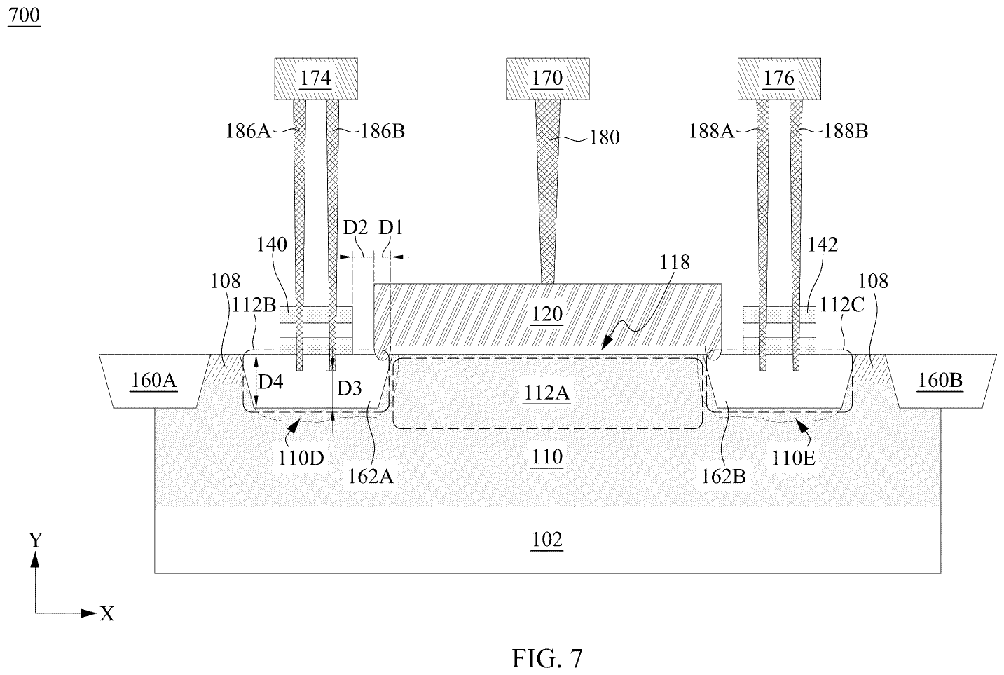

FIG. 7 illustrates a cross-section view of a semiconductor device 700 with multi-layer structures 140 and 142, in accordance with some embodiments of the present disclosure. The semiconductor device 700 of FIG. 7 can be similar to the semiconductor device 500 of FIG. 5, except for the differences described as follows.

In some embodiments, the multi-layer structure 140 can be electrically connected to the contact 174 for receiving a first biasing voltage to control or operate the semiconductor device 700. The first biasing voltage can be provided from an external power supply source. The first biasing voltage can be different from the gate voltage. The multi-layer structure 140 can be electrically connected to the contact 174 through the vias 186A and 186B.

In some embodiments, the multi-layer structure 142 can be electrically connected to the contact 176 for receiving a second biasing voltage to control or operate the semiconductor device 700. The second biasing voltage can be provided from an external power supply source. The second biasing voltage can be different from the first biasing voltage and the gate voltage. The second biasing voltage can be identical to the first biasing voltage but different from the gate voltage. The multi-layer structure 142 can be electrically connected to the contact 176 through the vias 188A and 188B. In some embodiments, the multi-layer structure 140 and 142 can be electrically connected to different biasing voltages, and the turned-on voltages of the semiconductor device 700 can be modulated efficiently and effectively.

Some embodiments of the present disclosure provide a semiconductor device. The semiconductor device includes a conductive structure, a gate structure, a first biasing structure and a second biasing structure. The conductive structure is formed on a substrate and extends along a first axis. The gate structure is formed above a central area of the conductive structure along a second axis vertical to the first axis. The gate structure extends beyond the central area along the first axis. The first biasing structure is spaced apart from the gate structure and at least partially embedded within a first recessed isolation of the conductive structure. The second biasing structure is spaced apart from the gate structure and at least partially embedded within a second recessed isolation of the conductive structure. The central area is between the first recess area and the second area along the first axis.

Some embodiments of the present disclosure provide a semiconductor device. The semiconductor device includes a conductive structure, a gate structure, a first multi-layer structure and a second multi-layer structure. The conductive structure is formed on a substrate and extends along a first axis. The gate structure is formed above a central area of the conductive structure along a second axis vertical to the first axis. The gate structure comprises at least one protruding structure extending toward the conductive structure along the second axis. The first multi-layer structure is spaced apart from the gate structure and disposed on a first recessed isolation of the conductive structure. The second multi-layer structure is spaced apart from the gate structure and disposed on a second recessed isolation of the conductive structure, and the central area is between the first recessed isolation and the second recessed isolation along the first axis.

Some embodiments of the present disclosure provide a method for manufacturing a semiconductor device. The method includes forming a conductive structure on a substrate, wherein the conductive structure comprises a first recessed isolation, a second recessed isolation, and a central area between the first recessed isolation and the second recessed isolation along a first axis; providing a gate structure above the central area along a second axis vertical to the first axis, wherein the gate structure extends beyond the central area along the first axis; forming a first biasing structure spaced apart from the gate structure, wherein the first biasing structure is at least partially surrounded by the first recessed isolation of the conductive structure; and forming a second biasing structure spaced apart from the gate structure, wherein the second biasing structure is at least partially surrounded by the second recessed isolation of the conductive structure.

The foregoing outlines the structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a conductive structure, on a substrate and extending along a first axis;
a gate structure, above a central area of the conductive structure along a second axis vertical to the first axis, wherein the gate structure extends beyond the central area along the first axis;
a first biasing structure spaced apart from the gate structure and at least partially embedded within a first recessed isolation of the conductive structure; and
a second biasing structure spaced apart from the gate structure and at least partially embedded within a second recessed isolation of the conductive structure, the central area is between the first recessed isolation and the second recessed isolation along the first axis.

2. The semiconductor device of claim 1, wherein the gate structure comprises at least one protruding structure at a lateral side of the gate structure, and the protruding structure extends toward the conductive structure along the second axis.

3. The semiconductor device of claim 2, wherein a first distance between the first biasing structure and the protruding structure along the first axis is greater than a width of the protruding structure along the first axis, and a second distance between the first biasing structure and a bottom of the first recessed isolation along the second axis is greater than the width of the protruding structure.

4. The semiconductor device of claim 3, wherein the second distance is greater than or substantially identical to the first distance.

5. The semiconductor device of claim 1, wherein the gate structure is configured to receive a gate voltage, and the first biasing structure and the second biasing structure are configured to receive a biasing voltage different from the gate voltage.

6. The semiconductor device of claim 5, wherein:
when the gate voltage and the biasing voltage have the same polarity, an early turned-on voltage of the semiconductor device is enhanced; and
when the gate voltage and the biasing voltage have different polarities, an early turned-on voltage of the semiconductor device is avoided.

7. The semiconductor device of claim 1, wherein the gate structure is configured to receive a gate voltage, the first biasing structure is configured to receive a first biasing voltage, and the second biasing structure is configured to receive a second biasing voltage.

8. The semiconductor device of claim 7, wherein:
when the gate voltage, the first biasing voltage and the second biasing voltage have the same polarity, two early turned-on voltages of the semiconductor device are created; and
when the gate voltage, the first biasing voltage and the second biasing voltage have different polarities, an early turned-on voltage of the semiconductor device is avoided.

9. A semiconductor device, comprising:
a conductive structure, formed on a substrate and extending along a first axis;
a gate structure, formed above a central area of the conductive structure along a second axis vertical to the first axis, wherein the gate structure comprises at least one protruding structure extending toward the conductive structure along the second axis;
a first multi-layer structure, spaced apart from the gate structure and disposed on a first recessed isolation of the conductive structure; and
a second multi-layer structure, spaced apart from the gate structure and disposed on a second recessed isolation of the conductive structure, the central area is between the first recessed isolation and the second recessed isolation along the first axis.

10. The semiconductor device of claim 9, wherein each of the first multi-layer structure and the second multi-layer structure comprises a nitride layer sandwiched by two oxide layers.

11. The semiconductor device of claim 9, wherein the gate structure is configured to receive a gate voltage through a via, the first multi-layer biasing structure is configured to receive a biasing voltage through a first pair of vias, and the second multi-layer structure is configured to receive the biasing voltage through a second pair of vias.

12. The semiconductor device of claim 11, wherein the first pair of vias penetrate the first multi-layer biasing structure, and the second pair of vias penetrate the second multi-layer biasing structure.

13. The semiconductor device of claim 11, wherein:
when the gate voltage and the biasing voltage have the same polarity, an early turned-on voltage of the semiconductor device is enhanced; and
when the gate voltage and the biasing voltage have different polarities, an early turned-on voltage of the semiconductor device is avoided.

14. The semiconductor device of claim 9, wherein the gate structure is configured to receive a gate voltage through a via, the first multi-layer biasing structure is configured to receive a first biasing voltage through a first pair of vias, and the second multi-layer structure is configured to receive a second biasing voltage through a second pair of vias.

15. The semiconductor device of claim 9, wherein a first distance between the first multi-layer structure and the protruding structure along the first axis is greater than a width of the protruding structure along the first axis, and a second distance between the first multi-layer structure and a bottom of the first recessed isolation of the conductive structure along the second axis is greater than the width of the protruding structure.

16. The semiconductor device of claim 15, wherein the second distance is greater than or substantially identical to the first distance.

17. The semiconductor device of claim 15, wherein the first distance between the first multi-layer structure and the protruding structure along the first axis is substantially zero.

18. A method for manufacturing a semiconductor device, comprising:
forming a conductive structure on a substrate, wherein the conductive structure comprises a first recessed isolation, a second recessed isolation, and a central area between the first recessed isolation and the second recessed isolation along a first axis;
providing a gate structure above the central area along a second axis vertical to the first axis, wherein the gate structure extends beyond the central area along the first axis;
forming a first biasing structure spaced apart from the gate structure, wherein the first biasing structure is at least partially surrounded by the first recessed isolation of the conductive structure; and
forming a second biasing structure spaced apart from the gate structure, wherein the second biasing structure is at least partially surrounded by the second recessed isolation of the conductive structure.

19. The method of claim 18, further comprising:
forming a first multi-layer structure, spaced apart from the gate structure and disposed on the first recessed isolation of the conductive structure; and
forming a second multi-layer structure, spaced apart from the gate structure and disposed on a second recessed isolation of the conductive structure.

20. The method of claim 19, comprising:
forming a first pair of vias penetrating the first multi-layer biasing structure; and
forming a second pair of vias penetrating the second multi-layer biasing structure.
